(19) United States
(12) Patent Application Publication
(10) Pub. No.: US 2005/0158885 A1
(43) Pub. Date: Jul. 21, 2005

(54) Wet bench wafer floating detection system

(75) Inventors: Wen-Song Tseng, Taitung City (TW); Kuo-Liang Lu, Hsinchu City (TW)

Correspondence Address: STEPHEN B. ACKERMAN, 28 DAVIS AVENUE, POUGHKEEPSIE, NY, 12603, US

(73) Assignee: Taiwan Semiconductor Manufacturing Co.

(21) Appl. No.: 10/761,002

(22) Filed: Jan. 20, 2004

(51) Int. Cl. C25F 1/00; C25F 3/30; C25F 5/00; B08B 6/00; H01L 21/00; H01L 21/66; G01R 31/26

(52) U.S. Cl. 438/8; 134/1.3; 134/902

(57) ABSTRACT

A method and system for preventing wafer breakage during wet processing is desscribed. A wet processing tank is provided wherein a wafer is to be placed within the wet processing tank. A sensor is provided within the wet processing tank wherein the sensor continuously counts bubbles formed within the wet processing tank in a time interval. The sensor is queried wherein if a bubble count within the time interval exceeds a trigger point, then an alarm is given so that a process lot will not be entered into the wet processing tank.

### BACKGROUND OF THE INVENTION

(1) Field of the Invention

The present invention relates to wet processing of semiconductor wafers, and more particularly, to a method of detecting abnormal conditions in a wet processing tank so that wafer damage is prevented.

(2) Description of the Prior Art

In the manufacture of integrated circuits, a number of process steps require immersing a wafer or wafers into a tank of liquid for wet processing. These process steps include etching, photoresist stripping, cleaning, etc. One hazard of these wet processing steps is that excess bubbles in the tank will cause the wafers to float in the liquid and to break. There are often about 50 wafers at a time in the tank. The floating wafers may collide with other floating or non-floating wafers or with the wall of the tank, etc., and thus break.

U.S. Pat. No. 6,033,475 to Hasebe et al describes a method of removing bubbles from a developing solution. U.S. Pat. No. 4,917,123 to McConnell et al teaches that a rinsing fluid should be free from bubbles because bubbles trap particles. U.S. Pat. No. 6,312,597 to Mohindra et al shows that bubbles can trap particles. They show a tank design and screen to break up bubbles that form in the liquid. None of the references discusses bubbles formed during heating of the liquid or detection of the presence of bubbles.

### SUMMARY OF THE INVENTION

Accordingly, it is a primary object of the invention to provide an effective and very manufacturable process for preventing wafers from floating within a tank.

Another object of the present invention is to provide a process for detecting bubbles within a tank before the presence of the bubbles causes a wafer in the tank to float.

In accordance with the objects of this invention, a method for detecting the presence of bubbles in a wet processing tank is achieved. A wet processing tank is provided wherein a wafer is to be placed within the wet processing tank. A sensor is provided within the wet processing tank wherein the sensor continuously counts bubbles formed within the wet processing tank in a time interval. The sensor is queried wherein if a bubble count within the time interval exceeds a trigger point, then an alarm is given so that a process lot will not be entered into the wet processing tank.

Also in accordance with the objects of this invention, a wet processing system having the means to detect the presence of bubbles is achieved. The wet processing system comprises a wet processing tank wherein a wafer is placed within the wet processing tank, a sensor within the wet processing tank wherein the sensor continuously counts bubbles formed within the wet processing tank in a time interval, and an alarm wherein if a bubble count within the time interval exceeds a trigger point, then the alarm is triggered so that a process lot will not be entered into the wet processing tank.

### BRIEF DESCRIPTION OF THE DRAWINGS

In the following drawings forming a material part of this description, there is shown:

FIGS. 1 and 2 are cross-sectional representations of a wet processing tank of the present invention.

FIG. 3 is a flow chart showing the bubble detection scheme of the present invention.

FIG. 4 is a cross-sectional representation of a wet processing tank having a bubble sensor according to the present invention.

### DESCRIPTION OF THE PREFERRED EMBODIMENTS

The process of the present invention provides a method for preventing wafer breakage in a wet processing tank by preventing floating of the wafers. The presence of bubbles in the tank will cause the wafers to float. Thus, the present invention adds a bubble detection sensor to the tank.

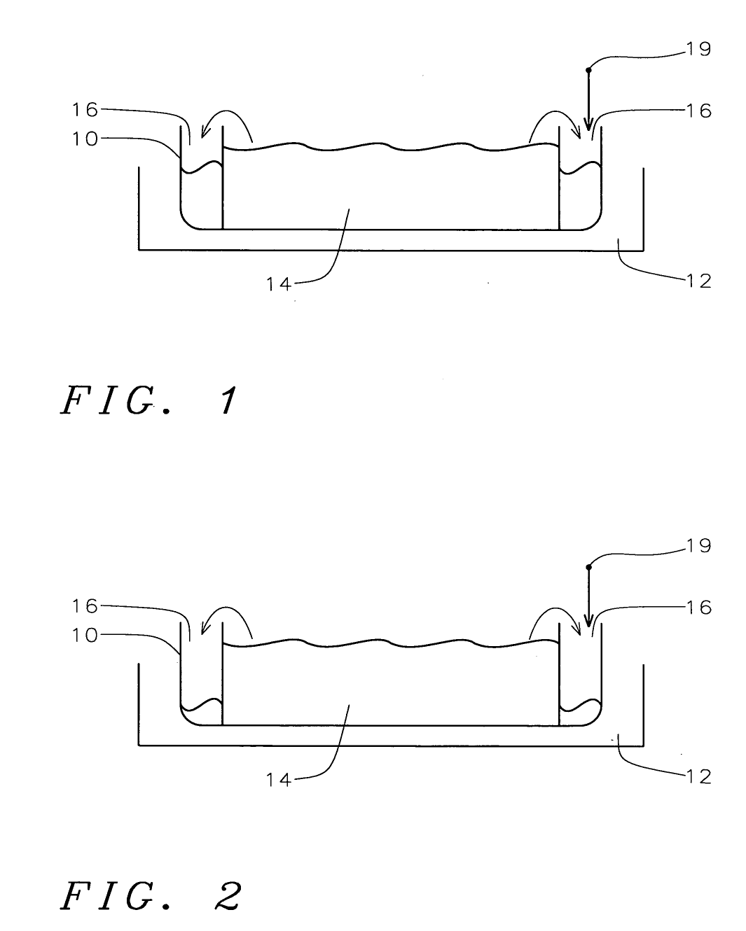

Referring now to FIG. 1, there is shown a wet processing tank 10 within a protection bath 12. Wafers are placed into the fluid-filled tank 14 that is surrounded by outer tank 16.

One example of a wet process is silicon nitride stripping. This is typically done in a solution of hot phosphoric acid (H₃PO₄). The etch reaction at about 160° C. is:
Si₃N₄+4H₃PO₄+10H₂O→Si₃O₂(OH)₈+4NH₄H₂PO₄
After dehydration and evaporation, we are left with an oxide precipitate and H₃PO₄. De-ionized water spiking 19 is added to the tank 16 for the process reaction. Refilling of the tank 16 with de-ionized water 19 affects the etch rate of the silicon nitride on the wafer, the boiling of the phosphoric acid, and the amount of dehydrated phosphoric acid produced. In the reaction function, it can be seen that H2O is the key factor in the Si3N4 reaction. As more water is added, the chemical liquid will begin to boil violently. Boiling causes bubbles which will cause the wafers to float. FIG. 2 shows the situation where the liquid in the outer tank 16 is low. If this liquid level is too low, air is sucked into the circulation loop. This will cause many bubbles in the tank, causing the wafer to float in the tank and possibly break.

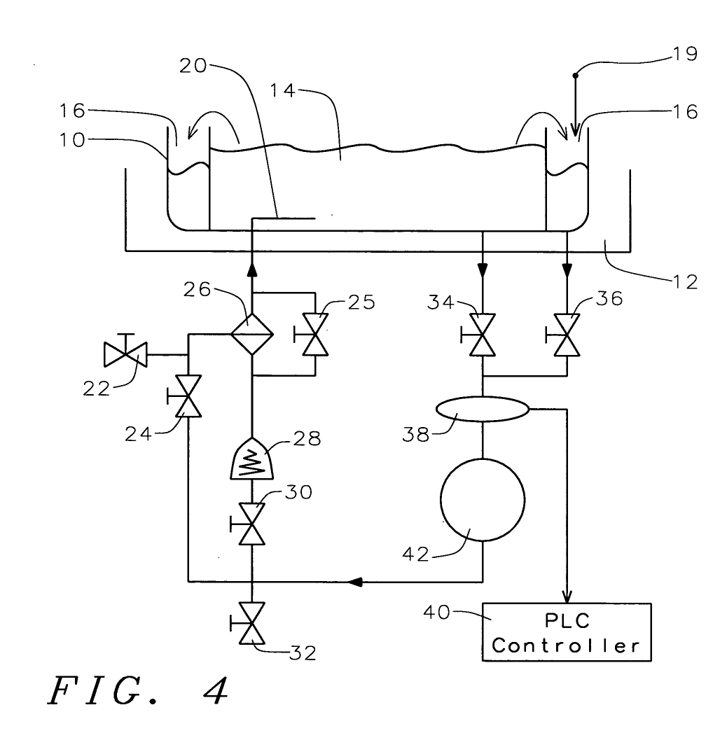

FIG. 4 shows the wet processing tank 10 with its circulation loop. The chemicals are continually in circulation as shown. From the outer tank 16, the liquid circulates through the air valve 36, through the circulation pump 42, through air valve 30, heater 28, filter 26, and into the inner tank 14 through the pipe 20. Also shown in FIG. 4 are an air valve 25 bypass loop, air valve drain filter 24, air valve 22 which serves as a sampling port, and drain valve 32. The bubble sensor of the present invention 38 is shown.

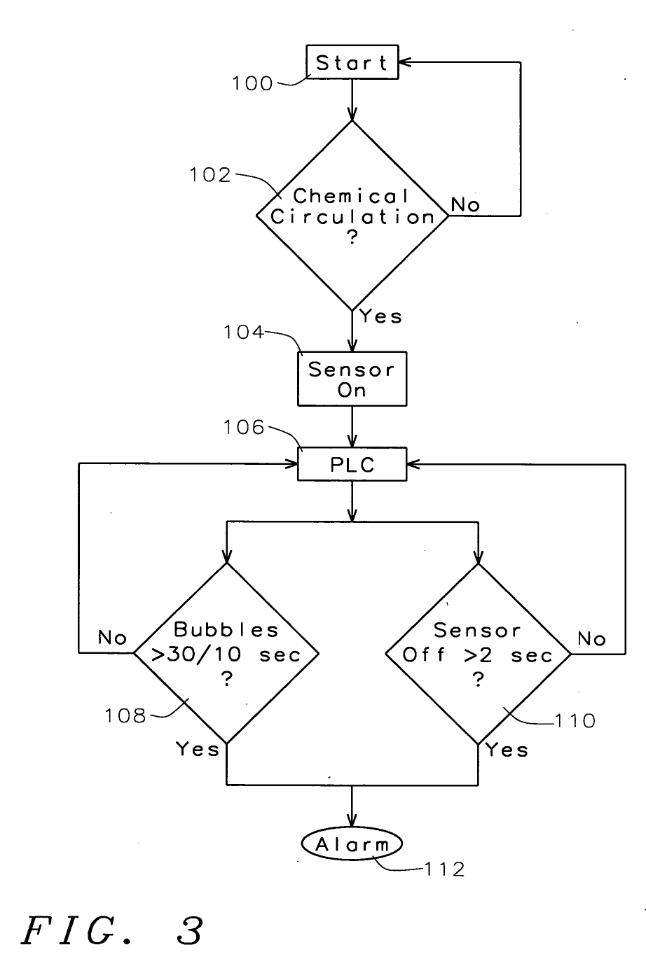

FIG. 3 is a flow chart showing the bubble detection scheme of the present invention. In step 102, a check is made for chemical circulation. Once chemical circulation is detected, the tank is in use and needs to be monitored. The bubble detection sensor (38 in FIG. 4) is turned on in step 104. The PLC controller 106 (40 in FIG. 4) continuously monitors the bubble sensor in two ways. In 108, bubbles within the tank 14 are counted in periods of 10 seconds. If there are more than 30 bubbles in 10 seconds, for example, this may be enough to cause wafers to float leading to breakage. Of course, the trigger number of bubbles in 10 seconds can be determined based on process conditions. If the trigger number of bubbles in 10 seconds is exceeded (in the example, more than 30 bubbles in 10 seconds), an alarm is given 112. The PLC controller also monitors the sensor to determine if it is off for more than two seconds, for example (step 110). If so, an alarm is given 112. When the alarm is received, the next processing lot is not entered into the tank. Operators can determine the cause of the bubbles or malfunction of the sensor and correct the problem before the next lot is entered.

The process of the present invention provides a method for preventing breakage of wafers within a wet processing tank. Excessive bubbling is detected before it can cause the wafers to float and thus to break.

While the invention has been particularly shown and described with reference to the preferred embodiments thereof, it will be understood by those skilled in the art that various changes in form and details may be made without departing from the spirit and scope of the invention.

1. A method for preventing wafer breakage in a wet processing tank comprising:
providing a wet processing tank wherein said wafer is to be placed within said wet processing tank;
providing a sensor within said wet processing tank wherein said sensor continuously counts bubbles formed within said wet processing tank in a time interval; and
querying said sensor wherein if a bubble count within said time interval exceeds a trigger point, then an alarm is given and said wafer is not placed into said wet processing tank.

2. The method according to claim 1 further comprising turning on said sensor when chemical circulation occurs within said wet processing tank.

3. The method according to claim 1 further comprising checking if said sensor emits an “OFF” signal wherein if said “OFF” signal is emitted for more than a threshold time period, then said alarm is given and said wafer is not placed into said wet processing tank.

4. The method according to claim 1 wherein said wet processing comprises wet stripping, wet etching, or rinsing.

5. The method according to claim 1 wherein said bubbles are caused by boiling of liquid within said wet processing tank.

6. The method according to claim 1 wherein said bubbles are caused by air being sucked into a circulation loop and thus into said wet processing tank.

7. The method according to claim 2 further comprising providing an outer tank surrounding said wet processing tank wherein said chemical circulation comprises a chemical liquid circulating out of said outer tank, through a pump, and into said wet processing tank.

8. The method according to claim 7 wherein said chemical liquid further travels through a heater, a filter, and several air valves.

9. The method according to claim 7 wherein said chemical liquid travels through said sensor prior to traveling through said pump.

10. A wet processing system comprising:
a wet processing tank wherein a wafer is to be placed within said wet processing tank;
a sensor within said wet processing tank wherein said sensor continuously counts bubbles formed within said wet processing tank in a time interval; and
an alarm wherein if a bubble count within said time interval exceeds a trigger point, then said alarm is triggered and said wafer is not placed into said wet processing tank.

11. The system according to claim 10 wherein said sensor is turned on when chemical circulation occurs within said wet processing tank.

12. The system according to claim 10 wherein if said sensor emits an “OFF” signal for more than a threshold time period, then said alarm is given and said wafer is not placed into said wet processing tank.

13. The system according to claim 10 wherein said wet processing comprises wet stripping, wet etching, or rinsing.

14. The system according to claim 10 wherein said bubbles are caused by boiling of liquid within said wet processing tank.

15. The system according to claim 10 wherein said bubbles are caused by air being sucked into a circulation loop and thus into said wet processing tank.

16. The system according to claim 10 further comprising:
an outer tank surrounding said wet processing tank;
a de-ionized water inlet into said outer tank; and
a circulation loop comprising a chemical liquid circulating out of said outer tank, through a pump, and into said wet processing tank wherein said chemical liquid travels through said sensor prior to traveling through said pump.

17. The system according to claim 16 wherein said circulation loop further comprises:
a plurality of air valves;
a heater;
a filter; and
a drain.

18. The system according to claim 16 wherein said wet processing tank overflows into said outer tank.

19. A method for preventing wafer breakage in a wet processing tank comprising:
providing a wet processing tank comprising a protection tank within which is provided an inner tank and an outer tank surrounding said inner tank wherein a plurality of wafers are to be placed within said inner tank;
providing a chemical circulation loop comprising a chemical liquid circulating out of said outer tank, through a pump, and into said inner tank;
providing a sensor within said chemical circulation loop wherein said chemical liquid travels through said sensor prior to traveling through said pump wewt wherein said sensor continuously counts bubbles formed within said inner tank in a time interval; and
querying said sensor wherein if a bubble count within said time interval exceeds a trigger point, then an alarm is given and said plurality of wafers are not placed into said inner tank.

20. The method according to claim 19 further comprising turning on said sensor when chemical circulation occurs within said chemical circulation loop.

21. The method according to claim 19 further comprising checking if said sensor emits an “OFF” signal wherein if said “OFF” signal is emitted for more than a threshold time period, then said alarm is given and said plurality of wafers are not placed into said inner tank.

22. The method according to claim 19 wherein said wet processing comprises wet stripping, wet etching, or rinsing.

23. The method according to claim 19 wherein said bubbles are caused by boiling of liquid within said inner and/or outer tanks.

24. The method according to claim 19 wherein said bubbles are caused by air being sucked into said circulation loop.

25. The method according to claim 19 wherein said chemical liquid further travels through a heater, a filter, and several air valves.
